(19) United States
(12) Patent Application Publication
(10) Pub. No.: US 2006/0258053 A1
(43) Pub. Date: Nov. 16, 2006

(54) Method for manufacturing electronic component-embedded printed circuit board

(75) Inventors: Doo Hwan Lee, Gyeonggi-do (KR); Chang Sup Ryu, Daejeon (KR); Han Seo Cho, Daejeon (KR); Byoung Youl Min, Gyeonggi-do (KR)

Correspondence Address: GOTTLIEB RACKMAN & REISMAN PC, 270 MADISON AVENUE, 8TH FLOOR, NEW YORK, NY, 100160601, US

(73) Assignee: SAMSUNG ELECTRO-MECHANICS CO., LTD.

(21) Appl. No.: 11/431,742

(22) Filed: May 9, 2006

(30) Foreign Application Priority Data
May 10, 2005 (KR) 10-2005-0038949

(51) Int. Cl. H01L 21/00

(52) U.S. Cl. 438/118

(57) ABSTRACT

Disclosed herein is a method for manufacturing a component-embedded printed circuit board that is economically advantageous and simple. The method is characterized by stacking boards in which a high density of electronic components are mounted to form a core layer in which the electronic components are embedded, and by subsequently building up additional circuit layers.

### BACKGROUND OF THE INVENTION

1. Field of the Invention

The present invention relates, in general, to a method for manufacturing a printed circuit board with electronic components embedded therein and, more particularly, to a method in which a core layer with electronic components embedded therein is formed by stacking electronic component-mounted boards, followed by building up circuit layers thereon, thereby significantly reducing the number of processes so as to produce the PCB at a minimum cost.

2. Description of Prior Art

Recently developed small portable electronic appliances, such as mobile phones, digital camcorders, digital cameras, personal digital assistants, portable computers, etc., require and are based on technologies for mounting a high density of electronic components. To meet requirement, printed boards tend to be stacked in a multilayer structure.

Typically, glass-epoxy resin impregnated circuit boards have multilayer structures with through-holes drilled therein. The circuit boards are highly reliable, but are difficult to use for high density packaging. As an alternative approach to achieve high circuit density, interconnections through via-contacts are employed so as to construct multilayer circuit boards.

Such via-contacts allow the shortest interconnections to be made between LSIs and components, and only necessary layers to be connected therebetween, making a great contribution to high density packaging.

Recently, much attention has been paid to printed circuit boards having components embedded therein due to their advantages over conventional ones. For example, component-embedded PCBs are multifunctional as well as being small relative to their capacity to be made highly functional. Additionally, component-embedded PCBs allow the shortest interconnections at high frequencies and, in some cases, offer solutions to the reliability problems found in W/B or solder balls of FC or BGA.

FIG. 1 is a cross-sectional view showing a component-embedded PCB manufactured according to a conventional SIMPACT process.

As shown FIG. 1, a component-embedded module comprises an electric insulation layer 101, an interconnection pattern 102, a via hole 103, and a solder 105, in addition to a one-sided substrate 109 having interconnection patterns 106, 108 and an inner via hole 107.

In order to solve the problem of heat dissipation occurring when components are mounted on one side of the substrate, the component-embedded PCBs additionally comprise an inner via hole 107 which is separately formed by laser or mechanical drilling.

Further, because the component-embedded PCB is manufactured through a lamination process following the formation of circuit patterns on the substrate, defects cannot be detected in an early stage.

FIG. 2 is a cross-sectional view showing a PCB with components embedded in both sides thereof, manufactured according to a conventional SIMPACT process.

As shown in FIG. 2, a component-embedded module comprises an insulation layer 212 with electronic components (active components 214a and passive components 214b) embedded therein, on either side of which a circuit board 211 is disposed. The circuit board 211 has an insulation substrate 211a with multilayer interconnection patterns formed therein. In addition, the electronic components 214a and 214b embedded in the insulation layer 212, with the interconnection patterns formed thereon and therein, are electrically connected with the interconnection patterns 217 formed on the circuit board 211. Extending through the insulation layer 212 in a vertical direction, inner vias 213 electrically connect the interconnection patterns 217 formed on a pair of the circuit boards 211 facing each other. The active components 214a electrically communicate with the interconnection patterns 217 through a bump 215, the contacts being sealed with resin 218. The passive components 214b also electrically communicate with the interconnection patterns 217 via a connection member 216.

Like that of FIG. 1, the component-embedded module of FIG. 2 suffers from the problem of heat dissipation because components are mounted on the circuit pattern-formed substrate. Also, because the component-embedded PCB is manufactured through a lamination process following the formation of circuit patterns on the substrate, defects cannot be detected early.

### SUMMARY OF THE INVENTION

Therefore, it is an object of the present invention to provide a method for manufacturing an electronic component-embedded PCB, which is economically advantageous and simple.

It is another object of the present invention to provide a method for manufacturing an electronic component-embedded PCB, which can ferret out defective boards in an early stage after the electronic components are mounted.

In accordance with the present invention, the above objects could be accomplished by the provision of a method for manufacturing a component-embedded printed circuit board, comprising: mounting electronic components on one side of a first metal foil; disposing a lamination member between the first metal foil and a second metal foil, the electronic component-mounted surface of the first metal foil facing the lamination member; pressing the first metal foil and the second metal foil against the lamination member to form a core layer in which the electronic components are embedded in the lamination member; and forming circuit patterns on the first metal foil and the second metal foil.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a PCB having electronic components embedded in one side thereof, manufactured according to a conventional SIMPACT (System in module using passive and active component embedding technology) process;

FIG. 2 is a cross-sectional view showing a PCB having electronic components embedded in both sides thereof, manufactured according to a conventional SIMPACT process;

FIGS. 3A to 3O are cross-sectional views showing a method for manufacturing a component-embedded PCB in accordance with an embodiment of the present invention; and

FIGS. 4A to 4N are cross-sectional views showing a method for manufacturing a component-embedded PCB in accordance with another embodiment of the present invention.

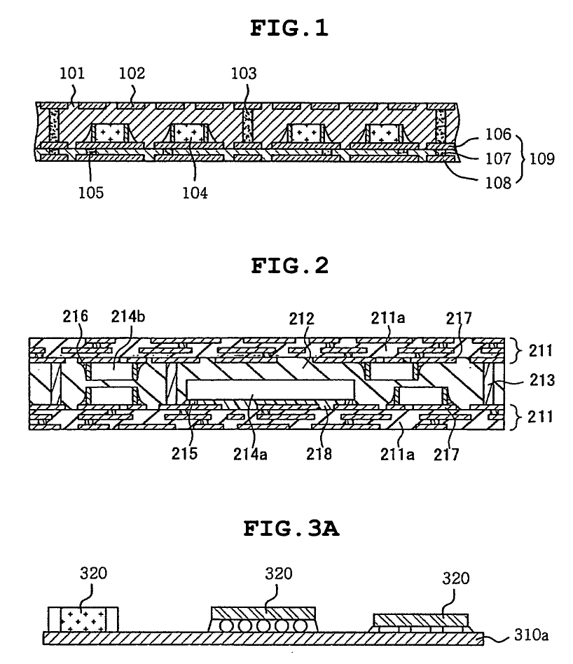

### DESCRIPTION OF THE PREFERRED EMBODIMENTS

A detailed description will be given of the present invention below, with reference to the accompanying drawings.

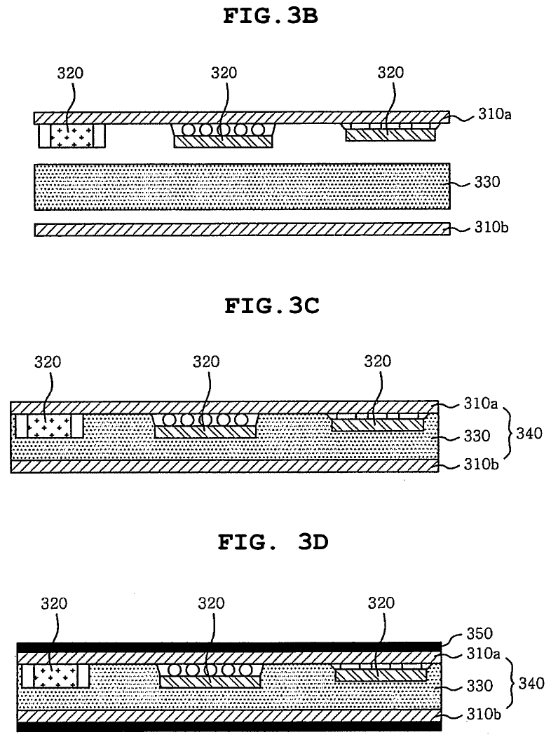

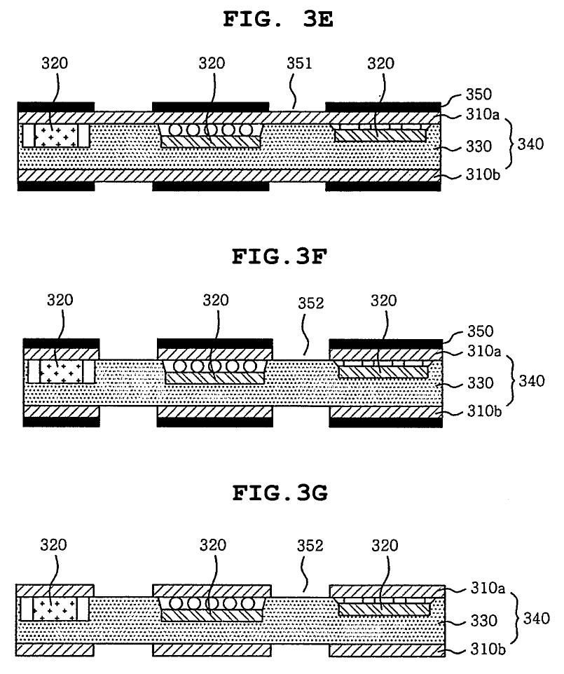

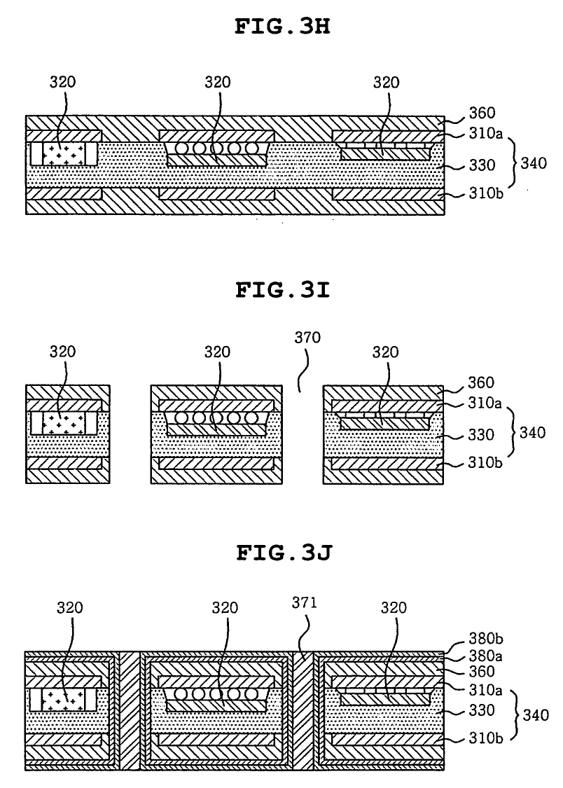

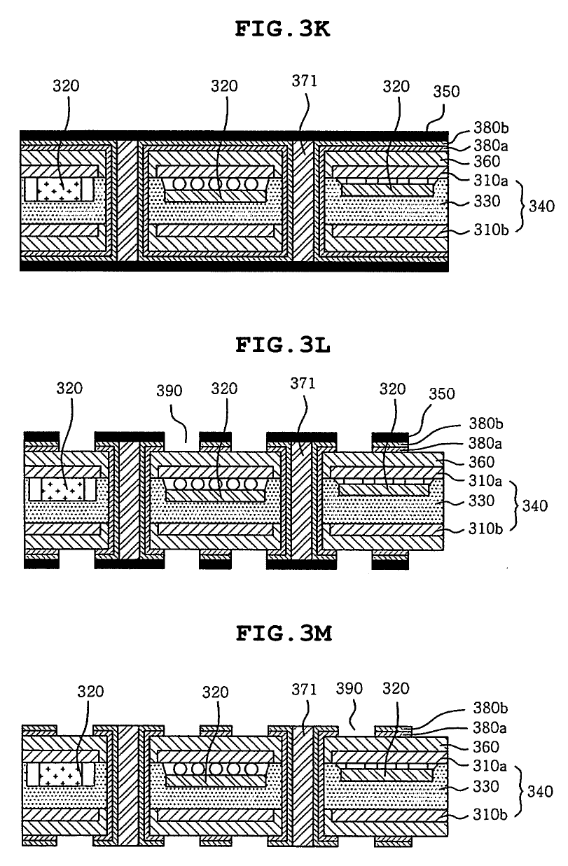

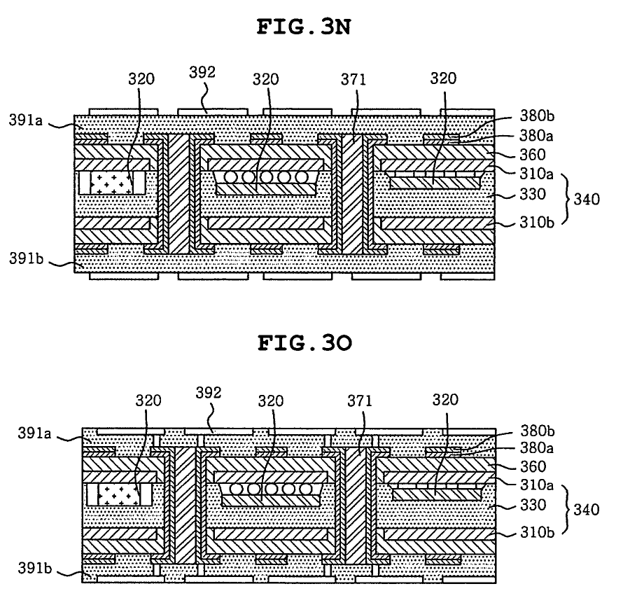

Referring to FIGS. 3A to 3O, cross-sectional views are provided for illustrating a method for manufacturing a component-embedded PCB in accordance with an embodiment of the present invention.

First, electronic components 320, as shown in FIG. 3A, are mounted on a first metal foil 310a, with an electrical connection between the electronic components 320 and the first metal foil 310a.

As the first metal foil 310a, a copper foil may be preferable. To have appropriate rigidity, the copper foil may be thick, or may be backed with a stiffener. In this case, the stiffener may be attached via tape to the copper foil. Preferably, the tape may be a heat or UV detachable type to facilitate lamination.

In contrast to conventional PCBs with embedded electronic components which require laser or mechanical drilling for cavity formation, the use of the copper foil as the first metal foil 310a allows electronic components to be embedded without laser or mechanical drilling. Further, the copper foil allows omission of a BVH (Blind Via Hole) formation process, which has been recognized as indispensable, thereby significantly reducing the production cost.

The electronic components 320 may comprise active components (e.g., transistors, operational amplifiers (OPAMPs), etc.) that have inputs and outputs and show constant relationships between inputs and outputs even simply upon electric application thereto, and/or passive components (e.g., resistors, inductors, capacitors, etc.) that cannot work by themselves but can function only in combination with active components.

Using a screen printing technique, electrically conductive paste, an anisotropic conductive film (ACF) or solder or a nonconductive paste (NCP) by dispensing, etc, may be applied to one side of the copper foil, in advance.

The electronic components utilize any one of copper, an ACF, and solder as an electrode therefor. In the case of copper, gang bonding is possible. Alternatively, FC connection is applied to the electrode of the electronic components. Following gang bonding or FC connection, underfill may be needed. It is difficult to achieve the best design. In practice, underfill is usually required due to its high physical resistance, such as resistance to drop impact, PCB dislocation impact (PCB distortion upon PCB assembly with elements or use by consumers), etc., and high chemical resistance, such as heat shock due to temperature change upon use, malfunction due to α-rays emitted from lead, etc.

FIG. 3B is a cross-sectional view after a lamination member 330 is placed between the first metal foil 310a and a second metal foil 310b such that the surface of the first metal foil 310a on which the electronic components 320 are mounted face the lamination member 330. Depending on conditions, the lamination member 330 is preferably made from a B-stage thermosetting resin. The B-stage thermosetting layer overcomes the problem of delamination in the substrate or board upon the pressurization, to be described later.

FIG. 3C is a cross-sectional view after the first metal foil 310a and the second metal foil 310b are integrated into the lamination member by pressing both of them against the lamination member 330 to form a core layer 340. The pressing is performed by applying external heat to the lamination member. In the presence of heat, the B-stage thermosetting layer softens, so that the lamination member 330 can adhere closely to the first metal foil 310a and the second metal foil 310b without leaving any void therebetween. Serving as a buffer against the pressing, the softened B-stage thermosetting layer can solve the problem of delaminating the substrate and the board.

Typical B-stage thermosetting layers are reinforced with glass fibers so that they are likely to damage electronic components upon pressing. However, the lamination member used in the present invention has a high content of resin or may be processed in advance to have cavities in places where damage is expected upon pressing.

Following the formation of the core layer 340, a circuit may be patterned so as to detect defects primarily. Thus, the present invention can ferret out defective boards early compared to conventional techniques which can find defects only after the formation of the final circuit layer. This early detection of defective boards just after the formation of the core layer 340 well in advance of the formation of the final circuit layer enjoys the advantage of greatly reducing the production cost because the boards, if defective, are discarded without building up additional circuit layers.

FIG. 3D is a cross-sectional view after photosensitive layers 350 are provided for forming circuit patterns.

A photolithographic method or a screen printing method may be used for forming circuits. In the present invention, a photolithographic method is preferred. The photolithographic method may be sub-classified according to the sensitive material used: dry film and liquid sensitized material. In the present invention, a dry film is preferably used. Thus, the photosensitive layers are made from a dry film 350 which is comprised of a photoresist film, a mylar film for providing flexibility, and a cover film. The cover film is peeled off in a lamination process while the mylar film functions to protect the photoresist film in the lamination process and is peeled off just before a developing process.

FIG. 3E is a cross-sectional view after the dry film 350 aligned with the core layer 340 is etched to form an interconnection pattern 351. The formation of the interconnection pattern 351 is effected by light exposure and development, in that order.

In regard to the exposure, an artwork film (not shown) in the shape of the interconnection pattern 351 to be formed is layered closely on the dry film 350 which is then exposed to UV light to induce the photosensitive material to chemically change. Because it blocks UV light, the artwork film stuck fast to the dry film 350 protects the region of the interconnection pattern 351 from the UV light while allowing the other region of the dry film to be exposed to the UV light. The exposed region of the dry film 350 is cured whereas the non-exposed region remains unchanged.

Development is carried out to dissolve the non-exposed region, leaving the cured region of the dry film 350, which leads to the interconnection pattern 351. A 1% sodium carbonate (Na₂CO₃) or potassium carbonate (K₂CO₃) solution is usually used as a developer.

Surely, each electrical interconnection point of each electronic component, depicted in this patent documentation, should be differently interconnected into separated pad on board. However, for the convenience's sake, the detailed interconnection shape will be abbreviated thoroughly.

FIG. 3F is a cross-sectional view after an inner interconnection pattern 352 of the core layer 340 is formed with the interconnection pattern of the dry film 350 serving as an etching resist. It will be appreciated that the dry film interconnection pattern formed through photolithography is not responsible for the interconnection, but the resulting interconnection pattern of the copper foil effectively act as an interconnection means.

For the formation of the interconnection pattern of the copper foil, an etching method, an additive method or a screen printing method using conductive paste may be applied, with the etching method being preferred. When an etching method is applied, an iron chloride solution, a cupric chloride (CuCl₂) solution, an alkaline solution, or a hydrogen peroxide-sulfuric acid solution may be used as an etchant.

FIG. 3G is a cross-sectional view after the etching resist of the dry film 350 has been peeled off to reveal the inner interconnection pattern 352 of the metal foils 310a and 310b.

As a delamination solution for peeling off the etching resist, a sodium hydroxide or potassium hydroxide solution may be preferably used. When the hydroxide group of the delamination solution reacts with the carboxyl group of the dry film, this film comes off of the substrate.

FIG. 3H is a cross-sectional view after a blanket of an insulation layer 360 is deposited over the core layer 340 in which the interconnection pattern of the metal foils is exposed.

Generally, prepreg with Cu foil or resin coated Cu foil can be usually used for lamination process. The general process can be adapted in this process. But, as a more convenient and less stressful process such as film type lamination would be a better selection. In this patent, we will show the film type lamination process.

The insulation layer 360 prevents the direct contact of the interconnection pattern of the metal foils 310a and 310b with an electroless plated copper layer 380a and an electroplated copper layer 380b, which will be described later.

FIG. 3I is a cross-sectional view after via holes 370 are formed through the core layer 340 covered with the insulation layer 360.

Via holes 370 function to connect the first metal foil 310a with the second metal foil 310b and are formed by drilling. Following the drilling, a deburring process and a desmear process are conducted to remove various impurities or contaminants generated during the drilling. Generally, there are two types of holes formed through the board: one is to have components inserted therein so as to electrically communicate with the interconnections formed on the opposite side; and the other is only for electrical connection between two layers. In the present invention, only holes for electrical connection between two layers are employed.

The deburring process is done to remove copper foil burrs generated during the drilling, dust on the inner walls of the holes, and dust and fingerprints on the copper foils. In addition, the deburring process confers roughness to the surface of the copper foils to increase the adhesion of copper thereto in a plating process to be described later.

As for the desmear process, it aims to remove smears resulting from the melting of the substrate resin due to the heat generated upon drilling. Playing a critical role in degrading the quality of the copper plated on the inner sidewalls of the holes, such smears must be removed.

FIG. 3J is a cross-sectional view after copper is plated on inner sidewalls of the via holes 370, followed by filling a filler 371 in the via holes 370.

In order to plate the inner sidewalls of the via holes 370 with copper, an electroless plating process (380a) and an electroplating plating process (380b) are conducted sequentially. Generally, an electroless plating process is the only process that can provide conductivity for surfaces of non-conductors, such as resins, ceramics, glass, and the like. In the present invention, the inner sidewalls of the via holes 370 are plated with copper in an electroless plating manner to electrically communicate interlayer interconnections.

Due to the presence of the electroless plated copper layer 380a, electroplating can be conducted with copper. As a rule, an electroplating process is able to form thicker and higher quality plated layers than is an electroless plating process. As a result, the electroplated copper layer 380b is thicker and of higher quality than the electroless plated copper layer 380a.

The filler 371 is preferably a conductive paste.

FIG. 3K is a cross-sectional view after a blanket of a dry film 350 for an outer interconnection pattern is deposited over the resulting structure, in which the core layer 340 is plated with copper.

FIG. 3L is a cross-sectional view after a photolithographic process is conducted to form an outer interconnection pattern 390 with the dry film 350 serving as a mask. This process is similar to that for the formation of the inner interconnection pattern 352 described above.

FIG. 3M is a cross-sectional view after the dry film 350 has been removed to reveal the outer interconnection pattern of the electroless plated copper layer 380a and the electroplated copper layer 380b. This delamination process may be conducted in the same manner as described above.

FIG. 3N is a cross-sectional view after insulation layers 391a and 392b are deposited over the entire surface of the structure in which the outer interconnection pattern 390 is formed, followed by the formation of a circuit pattern 392 atop each of the insulation layers.

FIG. 3O is a cross-sectional view of a multilayer PCB after build-up has been accomplished through multilayer printing as described above.

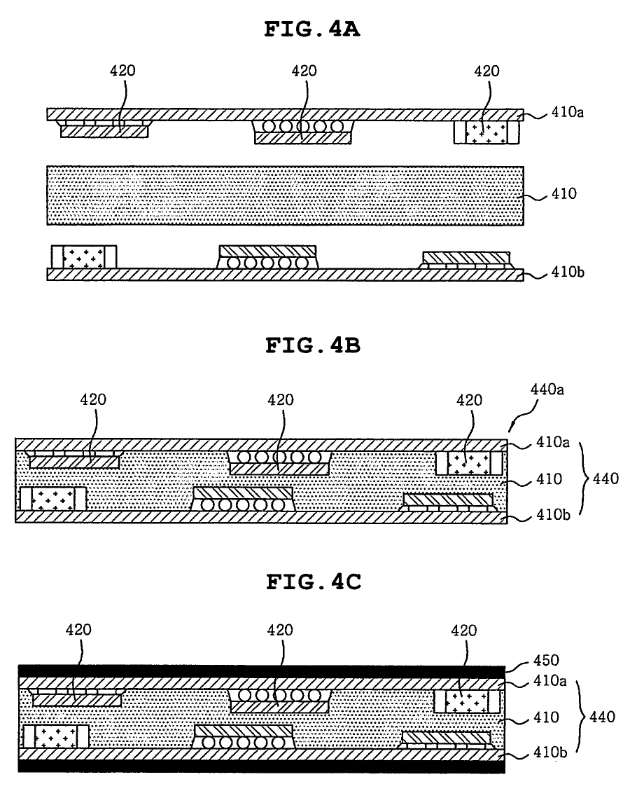

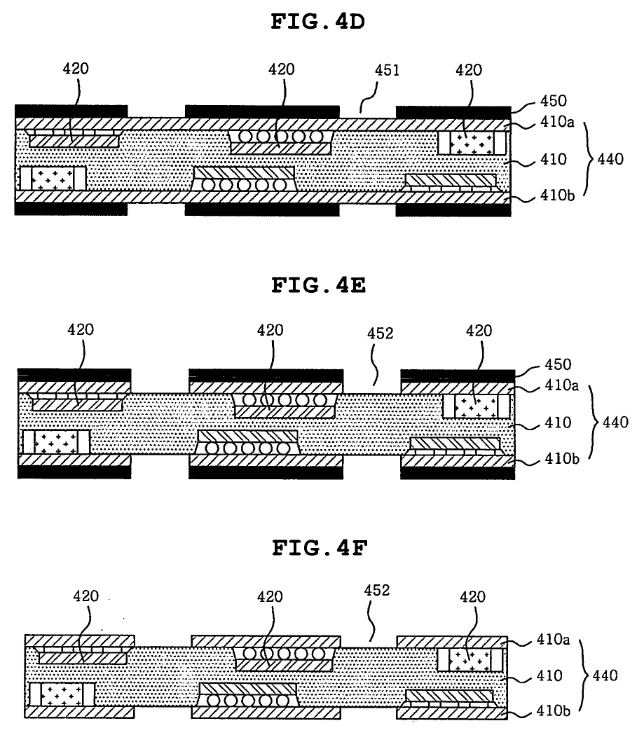

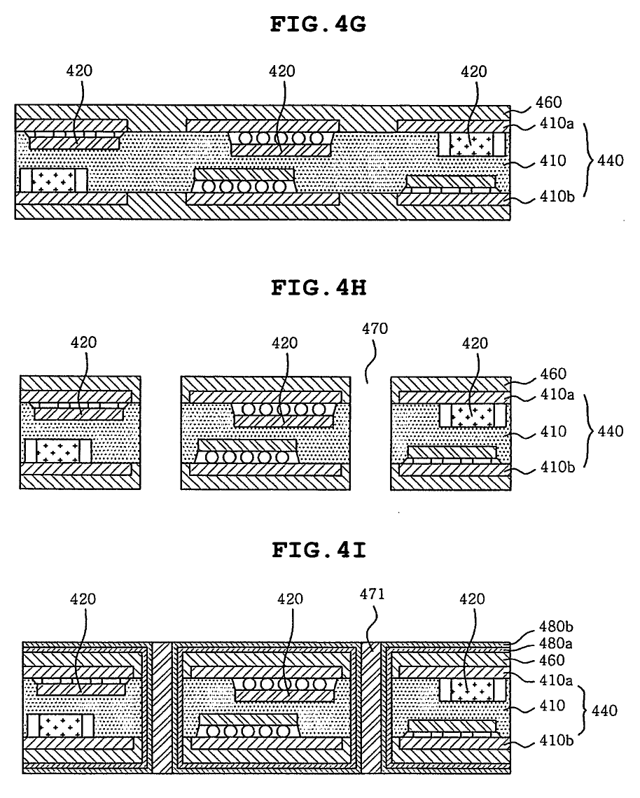

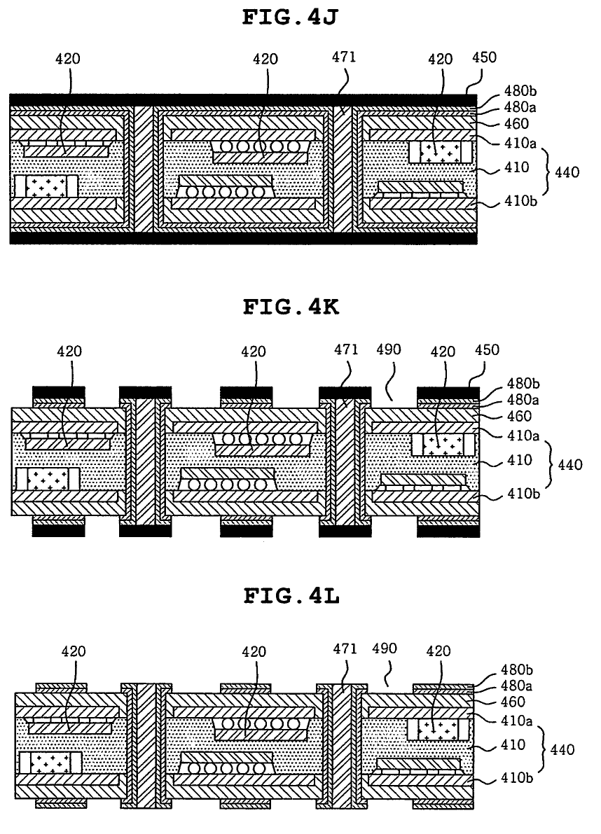

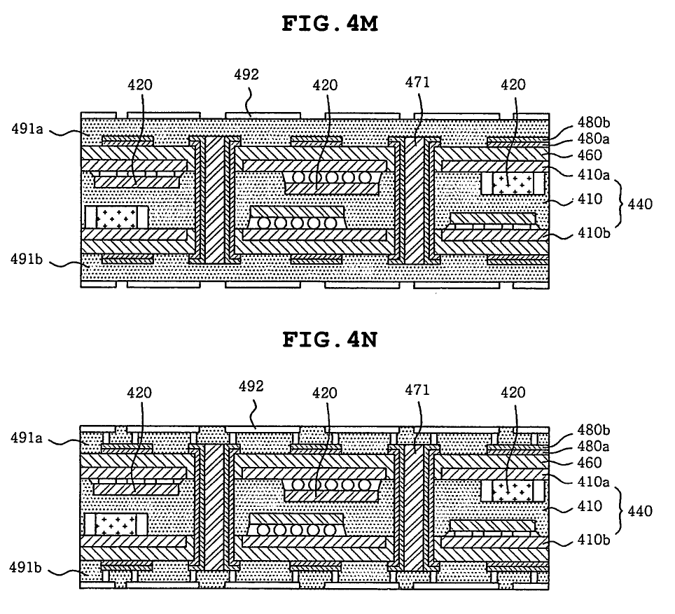

With reference to FIGS. 4A to 4N, cross-sectional views are provided for illustrating a method for manufacturing a component-embedded PCB in accordance with another embodiment of the present invention.

The method illustrated in FIGS. 4A to 4N is similar to that illustrated in FIGS. 3A to 30, with the exception that, instead of the second metal foil 310b, a second metal foil 410 on which electronic components are mounted is used so as to manufacture a PCB with electronic components embedded in both sides thereof.

In detail, as shown in FIG. 4A, electronic components 320 are mounted on a first metal foil 410a and a second metal foil 410b, with an electrical connections between the electronic components 420 and the first metal foil 410a and between the electronic components 420 and the second metal foil 410b, and a lamination member 410 is placed between the first metal foil 410a and a second metal foil 410b such that the component-mounted surface of each of the first metal foil 410a and the second metal foil 410b face the lamination member 410.

Both the first metal foil 410a and the second metal foil 410b are preferably made from copper foil. To have appropriate rigidity, the copper foil may be thick, or may be backed with a stiffener. In this case, the stiffener may be attached via tape to the copper foil. Preferably, the tape may be a heat or UV detachable type in view of lamination.

In contrast to conventional methods, in which electronic components 420s are mounted on circuit boards which have already had circuit patterns formed thereon, the use of the copper foil allows heat to be readily dissipated therefrom even if via holes for heat dissipation are not provided. Therefore, the present invention can greatly reduce the problem of heat dissipation occurring upon mounting a high density of integrated circuits even without additional laser or drilling processes.

The electronic components 420 may comprise active components (e.g., transistors, operational amplifier (OPAMP), etc.) that have inputs and outputs and show a constant relationship between inputs and outputs even simply upon electric application thereto, and/or passive components (e.g., resistors, inductors, capacitors, etc.) that cannot work by themselves, but can function only in combination with active components.

Using a screen printing technique, electrically conductive paste, an anisotropic conductive film (ACF) or solder or a nonconductive paste (NCP) by dispensing, etc, may be applied in advance to one side of the copper foil.

Depending on conditions, the lamination member 410 is preferably made from a B-stage thermosetting resin. The B-stage thermosetting layer overcomes the problem of delamination in the substrate or board upon the pressurization to be described later.

FIG. 4B is a cross-sectional view after the first metal foil 410a and the second metal foil 410b are integrated into the lamination member 410 by pressing both of them against the lamination member 410 to form a core layer 440. The pressing is performed with external heat applied to the lamination member. In the presence of heat, the B-stage thermosetting layer softens, so that the lamination member 410 can adhere closely to the first metal foil 410a and the second metal foil 410b without leaving any void therebetween. Serving as a buffer against the pressing, the softened B-stage thermosetting layer can solve the problem of delaminating the substrate and the board.

Typical B-stage thermosetting layers are reinforced with glass fibers so that they are likely to damage electronic components upon pressing. However, the lamination member used in the present invention has a high content of resin or may be processed in advance to have cavities in places where damage is expected upon pressing.

Following the formation of the core layer 440, a circuit may be patterned so as to detect defects primarily. Thus, the present invention can detect defective boards early compared to conventional techniques which can find defects only after the formation of the final circuit layer. This early detection of defective boards just after the formation of the core layer 440 well in advance of the formation of the final circuit layer enjoys the advantage of greatly reducing the production cost because the boards, if defective, are discarded without building up additional circuit layers.

FIG. 4C is a cross-sectional view after photosensitive layers 450 are provided for forming circuit patterns. A photolithographic method or a screen printing method may be used for forming circuits. In the present invention, a photolithographic method is preferred.

FIG. 4D is a cross-sectional view after the dry film 450 aligned with the core layer 440 is etched to form an interconnection pattern 451. The formation of the interconnection pattern 451 is effected by light exposure and development, in that order.

FIG. 4E is a cross-sectional view after an inner interconnection pattern 452 of the core layer 440 is formed with the interconnection pattern of the dry film 450 serving as an etching resist.

FIG. 4F is a cross-sectional view after the etching resist of the dry film 450 has been peeled off to reveal the inner interconnection pattern 452 of the metal foils 410a and 410b.

FIG. 4G is a cross-sectional view after a blanket of an insulation layer 460 has been deposited over the core layer 440 in which the interconnection patterns of the metal foils are exposed.

The insulation layer 460 functions to prevent the direct contact of the interconnection pattern of the metal foils 410a and 410b with an electroless plated copper layer 380a and an electroplated copper layer 380b, which are described later.

FIG. 4H is a cross-sectional view after via holes 470 are formed through the core layer 440 covered with the insulation layer 460.

FIG. 4I is a cross-sectional view after copper is plated on inner sidewalls of the via holes 470, followed by filling a filler 371 in the via holes 470.

In order to plate the inner sidewalls of the via holes 470 with copper, an electroless plating process (480a) and an electroplating process (480b) are sequentially conducted.

The filler 371 is preferably a conductive paste.

FIG. 4J is a cross-sectional view after a blanket of a dry film 450 for an outer interconnection pattern is deposited over the resulting structure in which the core layer 440 is plated with copper.

FIG. 4K is a cross-sectional view after a photolithographic process is conducted to form an outer interconnection pattern 490 with the dry film 450 serving as a mask. This process is similar to that for the formation of the inner interconnection pattern 452 described above.

FIG. 4L is a cross-sectional view after the dry film 450 has been removed to reveal the outer interconnection pattern 490 of the electroless plated copper layer 480a and the electroplated copper layer 480b. This delamination process may be conducted in the same manner as described above.

FIG. 4M is a cross-sectional view after insulation layers 491a and 492 b have been deposited over the entire surface of the structure in which the outer interconnection pattern 490 is formed, followed by the formation of a circuit pattern 492 atop each of the insulation layers.

FIG. 4N is a cross-sectional view of a multilayer PCB after build-up has been accomplished through multilayer printing as described above.

As described hereinbefore, the method for manufacturing a component-embedded PCB in accordance with the present invention can detect defective boards early, such as just after the formation of the core layer, compared to conventional techniques which can find defects only after the formation of the final circuit layer. This early detection of defective boards just after the formation of the core layer well in advance of the formation of the final circuit layer enjoys the advantage of greatly reducing the production cost because the boards, if defective, are discarded without building up additional circuit layers.

In contrast to conventional PCBs with embedded electronic components which require laser or mechanical drilling for cavity formation, the present invention requires no such laser or mechanical drilling processes for the formation of embedded components. Further, the present invention omits a BVH (Blind Via Hole) formation process, which was previously recognized as indispensable, thereby significantly reducing the production cost.

Additionally, the softened B-stage thermosetting layer used in the method of the present invention serves as a buffer against the pressing for embedding the components mounted on the metal foils and thus can solve the problem of delamination of the substrate and the board upon pressing.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

What is claimed is:

1. A method for manufacturing a component-embedded printed circuit board, comprising:
mounting electronic components on one side of a first metal foil;
disposing a lamination member between the first metal foil and a second metal foil, the electronic component-mounted surface of the first metal foil facing the lamination member;
pressing the first metal foil and the second metal foil against the lamination member to form a core layer in which the electronic components are embedded in the lamination member; and
forming circuit patterns on the first metal foil and the second metal foil.

2. The method according to claim 1, further comprising mounting electronic components on the second metal foil before the disposing step.

3. The method according to claim 1, wherein the first metal foil and the second metal foil are made from copper.

4. The method according to claim 1, wherein the electronic components are mounted on the first metal foil through electrical connection therebetween using a solder ball, an anisotropic conductive film, a conductive paste or a nonconductive paste, etc.

5. The method according to claim 1, wherein the electronic components are active components and/or passive components.

6. The method according to claim 1, wherein the lamination member is a B-stage thermosetting layer.
